(19) United States
(12) Patent Application Publication
(10) Pub. No.: US 2026/0333629 A1
(43) Pub. Date: Oct. 22, 2026

(54) SYSTEM AND METHOD FOR OVERHEATING PROTECTION

(71) Applicant: Aivres Systems Inc., Fremont, CA (US)

(72) Inventor: Wei Chang Chen, New Taipei City (TW)

(73) Assignee: Aivres Systems Inc., Fremont, CA (US)

(21) Appl. No.: 19/560,433

(22) Filed: Mar. 9, 2026

(51) Int. Cl. H05K 7/20; H05K 1/181

(52) U.S. Cl. CPC H05K 7/20281; H05K 1/181; H05K 2201/10022

(57) ABSTRACT

A circuit board includes a conductor; a thermistor thermally coupled with the conductor and configured to change an electrical resistance of the thermistor in response to a change in temperature of the conductor; and one or more controllers. The one or more controllers are configured to: obtain a signal based on a measurement of the electrical resistance of the thermistor; determine, based on the signal, that a threshold temperature associated with the conductor has been exceeded; and based on determining that the threshold temperature has been exceeded, generate a control signal for a subsystem to perform a temperature management response.

### BACKGROUND

Computer systems, such as servers, typically include peripheral temperature monitoring components such as voltage regulator (VR) controllers. These peripheral temperature monitoring components typically communicate with a baseboard management controller (BMC) via an inter-integrated circuit (I2C) bus. However, as the density of components within a computer system increases, demand increases proportionally for power supply infrastructure, space on a physical substrate of the computer system (e.g., wiring space, connector proximity, motherboard walking space), and communication ports (e.g., on an I2C bus). Moreover, as the number of components included in the computer system increases (e.g., as server power density increases), the number of components that need to have their temperature monitored increases due to the larger number of components and additional current being carried over those communication paths, further increasing demand for further communication ports for the I2C bus as well as physical space on the physical substrate to include the components and their I2C communication ports. Furthermore, by increasing the number of components communicating via the I2C bus (e.g., by including temperature monitoring components), communication between the I2C bus and the BMC is slowed down proportional to the number of lines of data being transmitted by the I2C bus.

Additionally, in high current circuits of the computer system, the local temperature of the high current circuits can increase quickly and significantly, potentially burning a substrate and/or component of the computer system. Typical computer systems rely on communication from peripheral devices via the I2C bus to report temperature measurements. However, communication via the I2C bus may not be fast enough to effectively respond to a local overheating before board burnout occurs, and this problem compounds as further components communicate over the I2C bus.

### SUMMARY

In an exemplary embodiment, a circuit board includes a conductor; a thermistor thermally coupled with the conductor and configured to change an electrical resistance of the thermistor in response to a change in temperature of the conductor; and one or more controllers configured to: obtain a signal based on a measurement of the electrical resistance of the thermistor; determine, based on the signal, that a threshold temperature associated with the conductor has been exceeded; and based on determining that the threshold temperature has been exceeded, generate a control signal for a subsystem to perform a temperature management response.

In a further exemplary embodiment, a method includes obtaining a signal based on a measurement of an electrical resistance of a thermistor, wherein the electrical resistance of the thermistor changes in response to a change in temperature of a conductor; determining, based on the signal, that a threshold temperature associated with the conductor has been exceeded; and generating a control signal for a subsystem to perform a temperature management response.

In yet a further exemplary embodiment, a non-transitory computer-readable medium has stored thereon a set of instructions, which if performed by one or more processors, cause the one or more processors to: obtain a signal based on a measurement of an electrical resistance of a thermistor, wherein the electrical resistance of the thermistor changes in response to a change in temperature of a conductor; determine, based on the signal, that a threshold temperature associated with the conductor has been exceeded; and generate a control signal for a subsystem to perform a temperature management response.

### BRIEF DESCRIPTION OF THE DRAWINGS

Systems and methods for non-intrusive overheating detection and hardware power loss protection are described in detail below with reference to the attached drawing figures, wherein:

FIG. 1 illustrates a schematic block diagram of a system according to one or more embodiments of the present disclosure;

FIG. 2A illustrates a block diagram of a circuit board system according to one or more embodiments of the present disclosure;

FIG. 2B illustrates a block diagram of a circuit board system according to one or more embodiments of the present disclosure; and

FIG. 3 illustrates a method for detecting and preventing overheating according to one or more embodiments of the present disclosure.

### DETAILED DESCRIPTION

The following detailed description is merely exemplary in nature and is not intended to limit the disclosure or the application and uses of disclosed embodiments and methods. Furthermore, there is no intention to be bound by any expressed or implied theory presented in the preceding background, summary, brief description of the drawings or the description that follows.

Systems and methods are disclosed herein that relate to non-intrusive overheating detection and hardware power loss protection, and in particular, for high current paths in servers. The systems and methods described herein can enhance fire prevention and hardware damage protection, in addition to enhancing the responsiveness of system management.

By way of example, the systems and methods utilize a controller (e.g., BMC, complex programmable logic device (CPLD), and/or an analog-to-digital convertor (ADC)) and thermistor(s) to quickly and non-intrusively monitor temperatures of high current paths without requiring additional I2C communication ports. A temperature monitoring method for a printed circuit board (PCB) (e.g., motherboard) helps to reduce I2C use and reduce the travel space burden, for instance when the terminal equipment does not have I2C interfaces for temperature monitoring. When the BMC detects that the temperature is too high and there is a risk of burning, the system may shut off the power (e.g., current) in time to avoid data and hardware damage. The approaches of the present disclosure may ensure that the server board has more monitoring of the source of high temperature generation so as to avoid burning (e.g., overheating and/or catching fire) the server board lines and components, thereby improving server security and reliability.

Among other aspects, the systems and methods provided herein may be used to automatically activate damage prevention processes (e.g., temperature management responses). For example, when a temperature monitoring process detects a safe temperature of a high current area (e.g., a threshold for a conductor) has been exceeded, the systems and methods can relay this measurement via communication paths separate from an I2C communication path and generate control signals to subsystems to mitigate the conditions triggering the threshold, thereby enhancing responsiveness of the system by avoiding additional I2C communication ports and I2C signals for temperature monitoring.

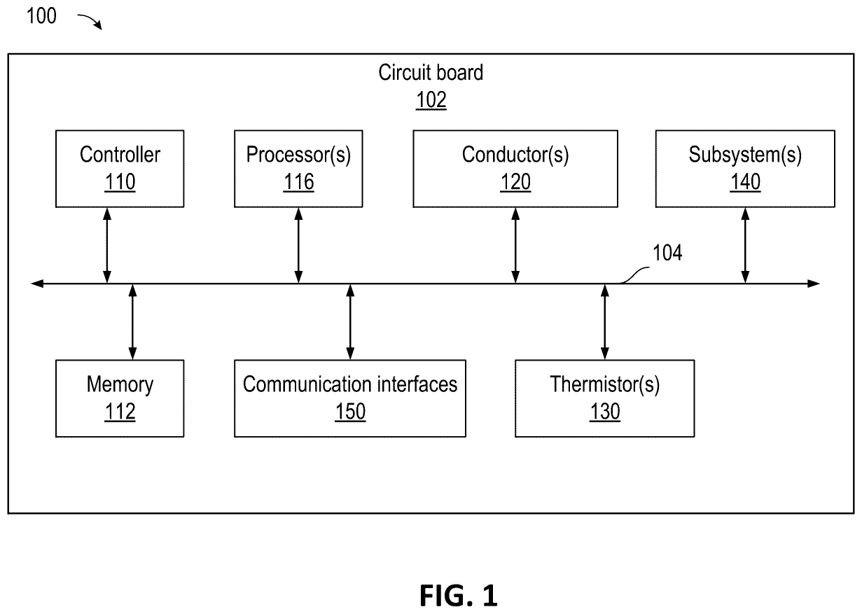

FIG. 1 illustrates a block diagram of a system 100, e.g., a circuit board 102 of a server, suitable for use in implementing embodiments of the present disclosure. It should be noted that the arrangements described herein, including this example, are provided for illustrative purposes only. Alternative configurations and components may be used in place of or in addition to those shown, and some components may be omitted entirely. Moreover, many of the elements described are functional in nature and can be implemented as standalone or distributed units, either independently or in combination with other components, and located in various configurations. Many of the functions discussed may be executed through hardware, firmware, and/or software, with processes typically performed by a processor running instructions stored in memory. Additionally, those skilled in the art will recognize that any system capable of performing the operations of the server system 100 falls within the scope and intent of the disclosed embodiments. Yet further, a person skilled in the art will recognize that the systems and methods described herein can be used with computer systems other than server systems.

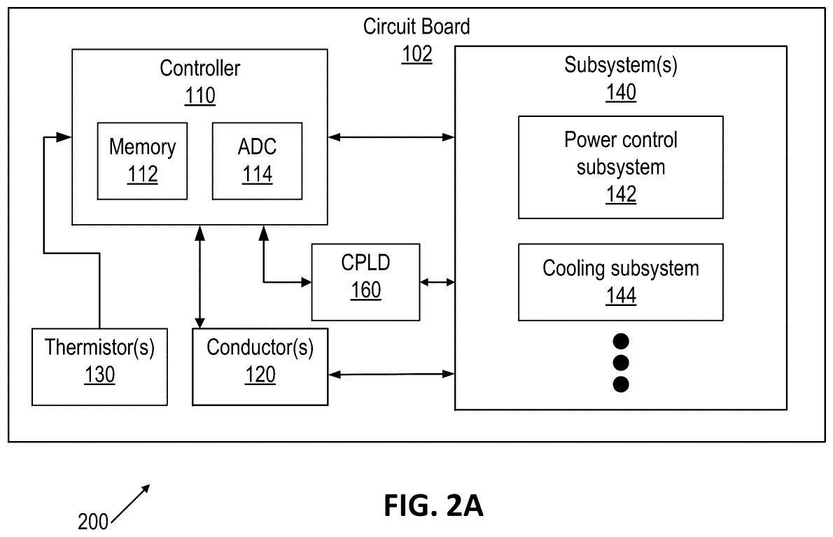

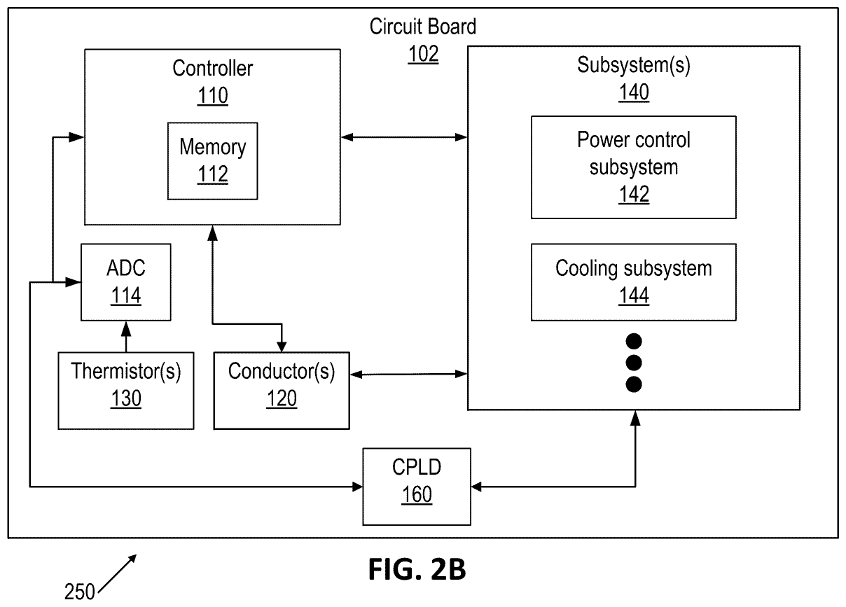

The system 100 includes one or more circuit boards 102 (e.g., a motherboard) that may carry various components, including hardware, firmware, and/or software, which may be integrated with, attached to, connected to, or in communication with the motherboard. As shown schematically in FIG. 1, the circuit board 102 carries at least one controller 110, one or more processors 116, memory 112, communication interfaces 150, one or more thermistor(s) 130, one or more conductor(s) 120, and one or more subsystem(s) 140. In some instances, the controller 110 is a BMC, which may or might not include an ADC. For instance, in some examples, the controller 110 is a BMC that includes an ADC. In other examples, the controller 110 is a BMC that does not include an ADC (e.g., the circuit board 102 may include an ADC that is separate from the BMC). In some variations, the controller 110 may be a CPLD. In other variations, the controller 110 may be separate from the CPLD, which is shown in more detail in FIGS. 2A and 2B (e.g., the controller 110 is separate from the CPLD 160). Such components and the circuit board 102 can communicate with one another through one or more buses 104 (e.g., integrated into the circuit board 102).

Processor(s) 116 may be configured to perform the operations in accordance with the instructions stored in memory 112, alone and/or in combination with the controller 110. In certain embodiments, the memory 112 may be integral to the processor(s) 116 and/or controller 110. In other embodiments, the memory may in whole or in part be separate from the processor(s) 116. Processor(s) 116 may include any appropriate type of general-purpose or special-purpose microprocessor (e.g., a central processing unit (CPU), graphics processing unit (GPU), and/or neural processing unit (NPU)), digital signal processor, microcontroller, or the like. Memory 112 may be configured to store computer-readable instructions that, when executed by processor(s) 116, can cause processor(s) 116 to perform various operations disclosed herein and/or store data relating thereto.

Memory 112 may be any non-transitory type of mass storage, such as volatile or non-volatile, magnetic, semiconductor-based, tape-based, optical, removable, non-removable, or other type of storage device or tangible computer-readable medium including, but not limited to, a read-only memory (“ROM”), EEPROM, a flash memory, a dynamic random-access memory (“RAM”), and/or a static RAM. In certain embodiments, memory 112 may include multiple storage devices of various types.

Controller 110 (e.g., BMC) may include a processing unit, internal memory (e.g., memory 112 as shown in FIG. 2A), programmable logic device (e.g., a CPLD), and communication interfaces (e.g., an ADC), and is configured to monitor and manage the hardware components of system 100 among other things. Controller 110 handles tasks such as remote system management, including hardware health monitoring, system event logging, temperature monitoring, and subsystem control. Controller 110 can operate independently of the system's 100 main processor (e.g., processor(s) 116), allowing for out-of-band management. Controller 110 may in certain embodiments facilitate communication with various sensors, such as other thermistor(s) 130 on the circuit board 102 to track temperature, fan speed sensors for a cooling subsystem of subsystem(s) 140, voltage levels for a power controller of a power control subsystem of subsystem(s) 140, and other parameters. Additionally, and/or alternatively, the controller 110 may include network interfaces and/or operate in conjunction with communication interfaces 150 to enable remote access for system administrators, providing a way to perform diagnostic tasks, power cycling, and firmware updates.

Conductor(s) 120 include components of the system 100 that conduct current. For example, conductor(s) 120 may include conductive wires and paths, busbars, semiconductors (e.g., metal-oxide-semiconductor field-effect transistors (MOSFETs)), capacitors, PCB traces, resistors, switches, gates, and/or any other structure that conducts electricity as part of a circuit. These structures, alone or in combination with each other, may provide connectors for expansion cards associated with processor(s) 116 (e.g., peripheral component interconnect express (PCIe) connectors) such as connectors (e.g., via a busbar and/or a radial socket (RadSOK)) between a GPU board and a mother board/back plane, connectors for expansion cards associated with memory 112 (e.g., serial AT attachment (SATA) connectors and/or next generation form factor (NGFF) connectors), board to board (BTB) connectors for electrically connecting one circuit board 102 to another circuit board of system 100, and/or connectors for sensors, cooling devices, power supply modules, clock generators, fan motors, and more, such as a connector between a cooling fan and the motherboard. Additionally, and/or alternatively, while busbar 104 is shown in FIG. 1 separately from the conductor(s) 120, conductor(s) 120 may include a busbar (e.g., busbar 104), as a busbar is able to conduct current for delivering electrical power and/or electrical signals between components. In other words, the busbar 104 may be considered a specific type of conductor 120, whether conducting electrical power between components or ground of a circuit board 102 and/or conducting current to convey signals between components of circuit board 102. Additionally, and/or alternatively, the conductor(s) 120 may include the circuit paths that provide power to the one or more components of the circuit board 102, such as the circuits that provide power from a power supply to the connectors for expansion cards associated with processor(s) 116 and/or memory 112, and/or the connectors for sensors, cooling devices, power supply modules, clock generators, and more.

Thermistor(s) 130 include one or more thermistors, a semiconductor type of resistor in which the resistance is dependent on temperature. The thermistor(s) 130 are configured to vary their resistance with temperature, and as a result, are configured to be used by the system 100 as a temperature sensor and/or control current as a function of temperature. The thermistor(s) 130 have a resistance that is proportional to their temperature. For example, a resistance of the thermistor(s) 130 may increase or decrease in proportion to a change in temperature. The thermistor(s) 130 are further configured to output an analog signal indicating their current resistance and/or temperature measurements.

Subsystem(s) 140 include one or more components of the system 100, such as power supply, power control, and/or cooling components. For instance, a subsystem 140 may include a power control subsystem, which includes a power supply and a power controller for selectively controlling the power supplied to one or more circuits. Additionally, and/or alternatively, a subsystem 140 may include a cooling subsystem, including one or more fans for an air cooling system and/or pumps for a liquid cooling system. The subsystem(s) 140 may be operated by controller 110 based on one or more control signals. Additionally, and/or alternatively, the subsystem(s) 140 may be operated passively independent of controller 110, while still able to be actively controlled by controller 110 based on one or more control signals.

Communication interfaces 150 may be configured to communicate information between system 100 and other devices or systems. For example, communication interfaces 150 may include an ADC for converting analog signals (e.g., from thermistor(s) 130) to digital signals. Additionally, and/or alternatively, communication interfaces 150 may include interfaces for various communication protocols, such as I2C communication protocols, serial peripheral interface (SPI) communication protocols, and/or universal asynchronous receiver/transmitter (UART) communication protocols. Additionally, and/or alternatively, communication interfaces 150 may include an integrated services digital network (“ISDN”) card, a cable modem, a satellite modem, and/or a modem to provide a data communication connection. As another example, communication interfaces 150 may include a local area network (“LAN”) card to provide a data communication connection to a compatible LAN. As a further example, communication interfaces 150 may include a high-speed network adapter such as a fiber optic network adaptor, 10G Ethernet adaptor, or the like. Wireless links can also be implemented by communication interfaces 150. In such an implementation, communication interfaces 150 can send and receive electrical, electromagnetic, or optical signals that carry digital data streams representing various types of information via a network. The network can typically include a cellular communication network, a Wireless Local Area Network (“WLAN”), a Wide Area Network (“WAN”), or the like.

The buses 104 may include one or more hardware components (e.g., a busbar with a two wire serial communication system for I2C communication and/or RadSOK). The buses 104 may also include separate communication infrastructures, such as direct hardware signaling infrastructure (e.g., for general purpose input/output (GPIO) communication) and/or communication for an ADC. Additionally, and/or alternatively, the buses 104 allow one or more components of the circuit board 102 to communicate with one or more components of the circuit board 102.

FIG. 2A is a block diagram illustrating a system 200, which may use a circuit board 102 using controller 110, thermistor 130, conductor 120, and subsystem 140 as in system 100 in accordance with one or more embodiments in the present disclosure.

As shown in FIG. 2A, controller 110 is configured to monitor, manage, and/or communicate with one or more components in the system 200, such as conductor(s) 120 and/or subsystems 140. The controller 110 (e.g., BMC) includes a memory 112, which in certain embodiments may be an internal memory, configured to store system logs, operational data, and other suitable data to manage hardware resources, log events, and provide remote access for system administrators. In certain embodiments, the memory 112 may temporarily store data for real-time tasks. For example, the memory 112 may store threshold data for reference when the controller 110 performs a determination regarding whether a signal from ADC 114 indicates a threshold has been exceeded. The controller 110 includes an ADC 114, and is configured to obtain from the thermistor(s) 130 an analog signal and, convert the analog signal to a digital signal to obtain the digital signal from the thermistor(s) 130. For example, the ADC 114 may be configured to continuously sample an analog output from the thermistor(s) 130, convert these samples into digital signals, and provide the signals to the controller 110.

The controller 110 is configured to generate and provide control signals to a CPLD 160 and one or more subsystems 140, including the power control subsystem 142, cooling subsystem 144, and/or one or more further subsystems. For example, the controller 110 may generate a control signal and provide the control signal directly to subsystem(s) 140 causing the subsystem(s) 140 to perform one or more temperature management responses for the conductor(s) 120. For instance, the power control subsystem 142 may shut off current to the circuit board 102, which may bypass any software control and/or processes and prevent burnout of the circuit board 102 due to overheating of the conductor(s) 120. Additionally, and/or alternatively, based on the control signal, the power control subsystem 142 may shut off current to a localized circuit of the identified conductor(s) 120, which may prevent burnout of the circuit board 102 due to overheating without requiring the entire circuit board 102 to lose current. Additionally, and/or alternatively, based on the control signal, cooling subsystem 144 may initiate and/or increase a mass flow of coolant to the conductor(s) 120, which may reduce and/or prevent the conductor(s) 120 from overheating.

Additionally, and/or alternatively, the controller 110 may generate a control signal and provide the control signal indirectly to subsystem(s) 140 by providing the control signal to the CPLD 160, instructing the CPLD 160 to cause the subsystem(s) 140 to perform one or more temperature management responses. The CPLD 160 may be configured to generate a hardware-based signal to for the one or more subsystem(s) 140. For example, based on a hardware-based control signal from the CPLD 160, the power control subsystem 142 may shut off current to the circuit board 102 and/or the cooling subsystem 144 may initiate and/or increase a mass flow of coolant. The controller 110 may be configured to communicate with the CPLD 160, subsystem(s) 140, and/or conductor(s) 120 via a first communication path, and to communicate with the thermistor(s) 130 via a separate analog communication path.

As shown in FIG. 2A, the thermistor(s) 130 may be arranged on the circuit board 102 adjacent to the conductor(s) 120. The conductor(s) 120 include any structures that conduct electrical current and as a result generate heat, such as but not limited to high current circuits, busbars, power connectors, and/or areas of circuit board 102. When arranged adjacent to the conductor(s) 120, the thermistor(s) 130 may be thermally coupled with the conductor(s) 120 via one or more of conduction, convection, or radiation. For example, when the thermistor(s) 130 are arranged directly adjacent to the conductor(s) 120, the thermistor(s) 130 may be subject to the same (or a substantially similar) temperature as the conductor(s) 120 due to heat radiating from the conductor(s) 120 to the thermistor(s) 130, through conduction from the conductor(s) 120 into an area of a substrate (e.g., the PCB or flexible substrate) of circuit board 102 shared by the thermistor(s) 130, and/or through convection from air moving from the conductor(s) 120 to the thermistor(s) 130, carrying the heat from the conductor(s) 120 to the thermistor(s) 130. Additionally, and/or alternatively, the thermistor(s) 120 may be located at a distance from the conductor(s) 120 while thermally coupled with conductor(s) 120 via a thermally conductive substance (e.g., solder trace and/or non-conductive heat transmission medium from conductor(s) 120 to thermistor(s) 130). Based on this thermal coupling, the resistance of the thermistor(s) 130 may act as a temperature sensor for the conductor(s) 120 by being subject to the same (or substantially similar) temperatures as the conductor(s) 120.

Thermistor(s) 130 may be arranged adjacent to individual conductor(s) 120 or a collection of conductor(s) 120. For example, a single thermistor 130 may be arranged on the circuit board 102 directly adjacent to a single conductor 120 (e.g., a busbar), and measure the temperature of that single conductor 120. Additionally, and/or alternatively, a single thermistor 130 may be arranged on the circuit board 102 directly adjacent to a plurality of conductor(s) 120, and measure the temperature of a collection of conductor(s) 120 (e.g., a surface area and/or collection of circuits of circuit board 102). Additionally, and/or alternatively, a plurality of thermistor(s) 130 may be arranged directly adjacent to a single conductor 120, and the plurality of thermistor(s) 130 may measure a same conductor 120. The thermistor(s) 130 may be arranged on the circuit board 102 by being mounted onto the circuit board 102 (e.g., via soldering). Additionally, and/or alternatively, the thermistor(s) 130 may use a connection point (e.g., connection pad, soldering pad) of the circuit board 102 that has been reserved for the thermistor(s) 130. Additionally, and/or alternatively, when the thermistor(s) 130 are arranged on the circuit board 102, the thermistor(s) 130 may be connected to an ADC via circuitry provided by the circuit board 102, such as via PCB traces of circuit board 102. For example, the thermistor(s) 130 may be soldered onto a connection point near one or more conductor(s) 120 and be connected to an ADC circuitry (e.g., of controller 110) using a PCB trace.

Moreover, each of thermistor(s) 130 may be identified by controller 110 with corresponding conductor(s) 120 the thermistor(s) 130 measure. Controller 110 may obtain a signal from a thermistor 130, reference (e.g., retrieve) one or more thresholds stored in memory 112, and determine both whether a threshold has been exceeded and which of conductor(s) 120 has exceeded that threshold based on the identified corresponding conductor 120 to the thermistor 130 from which the signal was obtained.

FIG. 2B illustrates a system 250 according to an embodiment of the present disclosure having an ADC 114 separate from the controller 110. The system 250 may include the same hardware, and hardware arrangements, and may be configured to perform the same functions as system 200 except where stated otherwise.

As shown in FIG. 2B, the ADC 114 may be a separate component from the controller 110. In the system 250, the ADC 114 may be an ADC. In some examples, the ADC 114 may include and/or be associated (e.g., connected to) further circuitry that enables the ADC 114 to determine, based on the obtained analog signal and using the further circuitry, that a threshold has been exceeded. For example, the ADC 114 may perform digital conversion of analog voltage and/or current variation signals detected by the thermistor(s) 130 and transmit the digitally converted signal via I2C and/or system management bus (SMBus) to the controller 110 and/or CPLD 160 for temperature reading. When the temperature (e.g., determined based on the signal received from the ADC 114) reaches a first threshold (e.g., a pre-alert threshold), the controller 110 and/or CPLD 160 controls the cooling device (e.g., increases a mass flow of coolant to the conductor(s) 120). Additionally, and/or alternatively, when internal logic of the further circuitry of ADC 114 detects that the converted current temperature value exceeds a second threshold (e.g., a set burnout threshold), the further circuitry of the ADC 114 may immediately trigger a hardware interrupt pin of the ADC 114 (e.g., pulls ALERT# or INT# low) that sends a signal to the CPLD 160 and/or the controller 110. Upon receiving the interrupt signal, the CPLD 160 immediately powers off the power supply (e.g., the power supply for conductor(s) 120 and/or the board 102), and simultaneously the controller 110 may, upon receiving this interrupt signal, write this critical abnormal event to the system event log.

In response to the further circuitry determining that a threshold has been exceeded, the further circuitry may provide the digital signal from the thermistor(s) 130 to the controller 110 for the controller 110 to generate a control signal for the subsystem(s) 140. In other words, the further circuitry may provide the digital signal to the controller 110 based on a threshold being exceeded. Additionally, and/or alternatively, in response to the further circuitry determining that a threshold has been exceeded, the further circuitry may provide the digital signal to the CPLD 160 for the CPLD 160 to generate a control signal for one or more subsystem(s) 140 to perform one or more temperature management responses. For example, the ADC 114 may sample the analog output from the thermistor(s) 130 and, based on the further circuitry determining that the analog output indicates a first temperature threshold of the thermistor(s) 130 (being used to monitor the temperature of the conductor(s) 120) has been exceeded, provide a digital signal to the controller 110. The controller 110, based on obtaining the digital signal, may generate a software-based control signal for the cooling subsystem 144 or for CPLD 160 to generate a control signal for cooling subsystem 144. In response to the further circuitry determining that a second temperature threshold (e.g., having a higher temperature than the first temperature threshold) of the thermistor(s) 130 has been exceeded, the further circuitry may provide a digital signal directly to the CPLD 160 to generate a control signal for the power control subsystem 142 and provide a digital signal to the controller 110 for the controller 110 to log the event (e.g., the threshold being exceeded and associated information for diagnoses). In other words, in some examples, the ADC 114 may solely be configured to obtain analog signals, convert the analog signals to digital signals, and provide the digital signals to a further component such as the CPLD 160 and/or controller 110. In other examples, instead of the ADC 114 directly providing the digital signal to the further component, the ADC 114 may provide the digital signals to the further circuitry, and the further circuitry may determine when the first threshold and/or the second threshold have been exceeded, and provide the digital signal to the further component, such as the CPLD 160 and/or controller 110.

It should be noted that the arrangements of system 100, system 200, and system 250 described herein, including this example, are provided for illustrative purposes only. Alternative configurations and components may be used in place of or in addition to those shown, and some components may be omitted entirely.

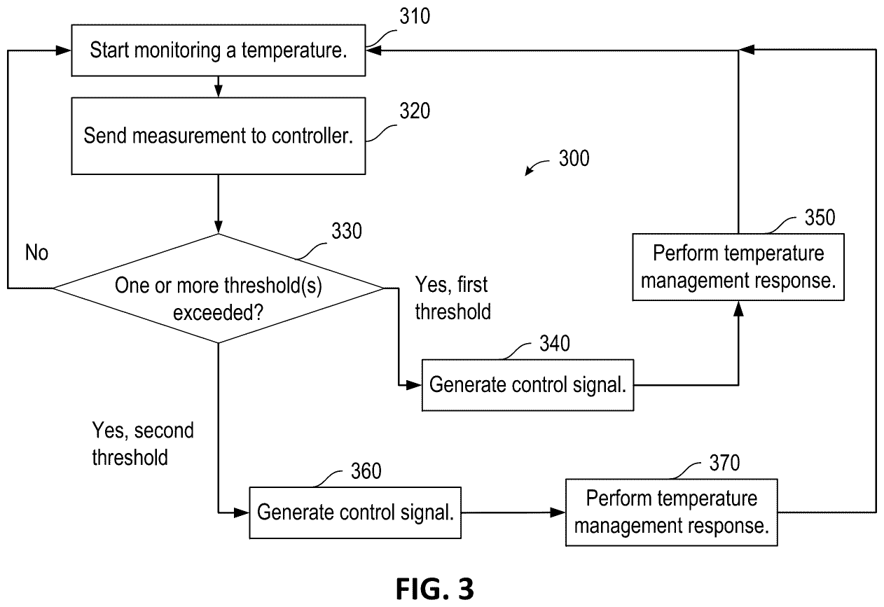

FIG. 3 illustrates a method 300 for protecting current paths from overheating, in accordance with one or more examples of the present disclosure. Method 300 may be performed by the systems 100, 200, and/or 250 as illustrated in FIGS. 1, 2A, and/or 2B or other suitable control devices. Method 300 may be performed alone or in combination with other processes in the present disclosure. It will be recognized that method 300 may be performed in any suitable environment and in any suitable order except where otherwise apparent. Alternative steps/stages may be performed instead of or in addition to those shown, and some steps/stages may be omitted entirely. These steps/stages can either serve as alternatives to each other or as subsequent steps/stages to each other. In certain embodiments, the controller may be embodied as a BMC (e.g., controller 110), an ADC (e.g., ADC 114 and included and/or associated further circuitry), and/or a CPLD (e.g., CPLD 160).

At stage 310, a thermistor (e.g., thermistor(s) 130) begins monitoring (e.g., measuring) a temperature of a conductor (e.g., conductor(s) 120). For example, the thermistor is configured such that the resistance of the thermistor changes in proportion to the temperature of the thermistor. Accordingly, when the thermistor is thermally coupled with the conductor, the temperature of the thermistor will change in proportion to any change of temperature in the conductor (e.g., when the conductor heats up, the thermistor also heats up). As a result, by measuring the resistance of the thermistor, a measurement of the temperature of the conductor and/or a change in temperature of the conductor (e.g., an indirect measurement) can be obtained. Additionally, and/or alternatively, the conductor may be a high current circuit including one or more conductive paths and/or components, such that the thermistor is able to change resistance (e.g., perform a measurement) in response to multiple different conductors.

At stage 320, a measurement of the temperature of the conductor is sent to a controller (e.g., the BMC). For instance, an ADC (e.g., ADC 114) of a controller (e.g., controller 110) may obtain an analog signal from the thermistor (e.g., containing information regarding the resistance and/or temperature of the thermistor) and convert this analog signal to a digital signal. In some embodiments, the ADC may sample a continuous input received from the thermistor and provide each sample to a controller. In some embodiments, when the ADC is separate from the BMC, the measurement of the temperature of the conductor is sent to the controller by the ADC obtaining the analog signal output from the thermistor.

At stage 330, the controller determines whether one or more threshold(s) have been exceeded (e.g., tripped) by determining a value from the signal equal to or greater than the threshold value. For example, the controller may determine whether the resistance and/or temperature measurements contained in the digital signal from the ADC indicate that a temperature threshold, temperature range threshold, and/or time temperature range threshold has been exceeded. In response to determining that no threshold has been exceeded, the method 300 reverts back to stage 320 and obtains further signals from the ADC. In response to determining that a threshold has been exceeded, the method 300 proceeds to either stage 340 or 360 based on which threshold has been determined to have been exceeded.

For example, the BMC may obtain from the ADC a value indicative of a temperature (e.g., of the thermistor and/or the conductor), and determine that a general (e.g., non-component and/or non-region specific) temperature threshold, temperature range threshold, and/or time temperature range threshold has been exceeded. Additionally, and/or alternatively, the ADC may provide a value (e.g., measured, determined, reported) indicative of the resistance of the thermistor directly to the BMC for the BMC to determine whether a threshold has been exceeded. The BMC may determine that the resistance of the thermistor has exceeded a defined threshold resistance value, threshold resistance range, and/or has remained within a defined threshold resistance range longer than a defined time. Additionally, and/or alternatively, the BMC may determine the temperature of the thermistor based on the resistance measurement from the digital signal and a known relationship (e.g., approximation, proportional change, temperature coefficient of resistance) between the temperature of the thermistor and the resistance of the thermistor. Using this determined temperature of the thermistor, the BMC may determine whether the temperature of the thermistor has exceeded a threshold temperature of the thermistor (e.g., 80 degrees centigrade, 100 degrees centigrade, 150 degrees centigrade, 370 Kelvin, 440 Kelvin) and/or achieved (e.g., reached or exceeded) a threshold temperature range of the thermistor (e.g., 75-95 degrees centigrade, 100-120 degrees centigrade, 150-155 degrees centigrade).

Additionally, and/or alternatively, using this determined temperature of the thermistor and a known relationship between the temperature of the thermistor and a temperature of the conductor (e.g., due to heat losses during thermal coupling from the conductor to the thermistor), the BMC may determine whether the temperature of the conductor has exceeded a threshold temperature of the conductor (e.g., 80 degrees centigrade, 85 degrees centigrade, 100 degrees centigrade, 110 degrees centigrade, 150 degrees centigrade, 370 Kelvin, 450 Kelvin) and/or a threshold temperature range of the conductor (e.g., 85-95 degrees centigrade, 90-120 degrees centigrade, 145-150 degrees centigrade). Additionally, and/or alternatively, the BMC may determine the temperature of the conductor (e.g., indirectly) based on the resistance measurement from the digital signal and a known relationship between the resistance of the thermistor and the temperature of the conductor, and using this determined temperature of the conductor, the BMC may determine whether the temperature of the conductor has exceeded a threshold temperature of the conductor and/or a threshold temperature range of the conductor. Additionally, and/or alternatively, the BMC may determine that the temperature of the thermistor and/or the conductor has remained within a defined temperature range of the conductor for longer than a defined amount of time (e.g., 6 milliseconds, 1 second, 60 seconds, 1 hour), and based on this determination, determine whether a time temperature range threshold has been exceeded.

Moreover, each threshold may be included in an associated plurality of thresholds, tiered based on their severity. For instance, as with the other thresholds described above, the determination of whether a temperature threshold has been exceeded may include a determination of which severity (e.g., early warning, failure prevention, critical response) of the temperature threshold has been exceeded (e.g., 80 degrees, 100 degrees, 120 degrees 150 degrees, or 200 degrees). Based on which severity of temperature threshold has been exceeded, the controller may generate a control signal for one or more temperature management responses and/or one or more respective subsystems corresponding to the determined severity level of the temperature threshold.

Additionally, and/or alternatively, at stage 330, the ADC may sample a continuous input from the thermistor and, using the further circuitry included and/or associated with the ADC 114 as in system 250, perform the determinations above regarding whether the analog signal received from the thermistor is indicative of a temperature exceeding a threshold (e.g., a thermistor temperature threshold, thermistor resistance threshold, and/or conductor temperature threshold) before, after, or simultaneously to sending the measurement to the controller.

At stage 340, in response to determining that a first threshold has been exceeded, the controller generates a control signal for a first subsystem to perform a first temperature management response. The control signal may be a software based control signal (e.g., generated and provided via an OS of the system) and/or a hardware based signal (e.g., generated using a hardware signaling interface and provided external to an OS of the system). For example, in response to determining that a first threshold temperature (e.g., 100 degrees centigrade) has been exceeded, the controller generates a control signal for a cooling subsystem to generate a mass flow to cool the conductor. For instance, the cooling subsystem may be a fan system, and the control signal may instruct the fan system to initiate or increase a fan speech of the fans to increase a mass flow of air onto the conductor (e.g., speed up the fans to increase air flow) as the first temperature management response. Additionally, and/or alternatively, the cooling subsystem may be a liquid cooling subsystem, and the control signal may instruct the liquid cooling subsystem to increase the mass flow of the coolant (e.g., increase a quantity or speed of the coolant) as the first temperature management response. Additionally, and/or alternatively, the controller generates the control signal for a first subsystem by providing a control signal to the CPLD (e.g., CPLD 160), instructing the CPLD to generate a control signal for the first subsystem.

Additionally, and/or alternatively, at stage 340, in embodiments where the further circuitry included and/or associated with the ADC determines that the first threshold has been exceeded (e.g., when the ADC is separate from the BMC), the further circuitry may provide a digital signal to a controller (e.g., a CPLD) causing the CPLD to generate a control signal to a corresponding subsystem such as the cooling subsystem, and provide a digital signal to another component of the controller (e.g., the BMC) for the controller to log the event.

At stage 350, in response to receiving the control signal from the controller, the first subsystem performs the first temperature management response. For example, in response to receiving the control signal, the fan system and/or liquid cooling subsystem may increase the mass flow onto the conductor to increase a cooling effect of the conductor (e.g., cool the conductor).

After performing the first temperature management response, the method 300 reverts to stage 310 and measures the temperature of the conductor. For instance, the controller may obtain a further signal from the thermistor to determine whether increasing the mass flow has success-fully cooled the conductor below the determined threshold. Obtaining the further signal from the thermistor may be based on performing the first temperature management response, or occur independently from and/or simultaneously to generating the control signal for the first subsystem to perform the first temperature management response.

At stage 360, in response to determining that a second threshold has been exceeded, the controller generates a control signal for a second subsystem to perform a second temperature management response. For example, in response to determining that a second threshold temperature (e.g., 140 degrees centigrade) has been exceeded, the controller generates a control signal for a power control subsystem to shut off power to the conductor. The control signal may instruct the power control subsystem to shut off power in a localized manner (e.g., only to the circuit of the conductor monitored by the thermistor) and/or may instruct the power control subsystem to shut off power to the entire system (e.g., the entire PCB on which the conductor is arranged and the power control subsystem powers, including all other components on the board). Additionally, and/or alternatively, the controller generates the control signal for the second subsystem by providing a control signal to the CPLD (e.g., CPLD 160), instructing the CPLD to generate the control signal for the second subsystem.

The determination that the second threshold has been exceeded may be performed based on the same signal upon which the determination that the first threshold has been exceeded was made (e.g., the method 300 may proceed to stage 340 and 360 simultaneously and/or subsequently to each other). For instance, if a thermistor measurement indicates a temperature of 150 degrees centigrade, this measurement may exceed both the first and the second thresholds, triggering both temperature management responses (e.g., sending both a first control signal for the first subsystem and a second control signal for a second subsystem) or the most severe temperature management response corresponding to the most severe threshold. Additionally, and/or alternatively, the determination that the second threshold has been exceeded may be performed based on a different signal than the signal upon which the determination that the first threshold has been exceeded was made (e.g., based on separate measurements from the thermistor). For example, the method may proceed from stage 330 to stage 340, from stage 340 to 350, from stage 350 to stage 310, from stage 310 to stage 320 again, and from stage 320 to stage 330 again before proceeding to stage 360.

Additionally, and/or alternatively, at stage 360, in embodiments where the further circuitry included and/or associated with the ADC determines that the second threshold has been exceeded (e.g., when the ADC is separate from the BMC), the further circuitry may provide a digital signal to a controller (e.g., the CPLD) causing the CPLD to generate a control signal to the corresponding subsystem such as the power control subsystem and provide a digital signal to another component of the controller (e.g., the BMC) for the controller to log the event.

Additionally, and/or alternatively the generation of a control signal at stage 360 may differ from a format of a control signal generated at stage 340. For example, the control signal generated at stage 340 (e.g., for a cooling subsystem) may be generated using a software-based control signal, and the control signal generated at stage 360 may be generated using a hardware-based control signal (e.g., for the power control subsystem), and vice-versa.

At stage 370, in response to receiving the control signal from the controller, the second subsystem performs the second temperature management response. For instance, in response to receiving the control signal, the power control subsystem may shut off power to the circuit of the conductor and/or the entire board.

After performing the second temperature management response, the method 300 reverts to stage 310. For instance, the thermistor may be arranged on a separate circuit from the conductor, such that when the power control subsystem shuts off power only to the circuit of the conductor, the thermistor continues to receive power enabling the thermistor to continue to monitor the temperature of the conductor until the controller obtains a signal from the thermistor indicating that a cooling threshold has been exceeded (e.g., the conductor has cooled below a restart temperature threshold of 40 degrees centigrade). Additionally, and/or alternatively, an external temperature monitoring component, powered by a circuit external to circuits powered by the power control subsystem, may provide a signal approving a restart of the system of method 300.

It should be understood that the method 300 may include more than two thresholds (e.g., first threshold and second threshold), a determination of whether more than two thresholds have been exceeded, more than two subsystems (e.g., first subsystem and second subsystem), and/or more than two temperature management responses. Moreover, it should be understood that the method 300 may include generating more than one control signal, one subsystem, and/or one temperature management response per exceeded threshold.

In an embodiment, a circuit board, comprises: a conductor; a thermistor thermally coupled with the conductor and configured to change an electrical resistance of the thermistor in response to a change in temperature of the conductor; and one or more controllers configured to: obtain a signal based on a measurement of the electrical resistance of the thermistor; determine, based on the signal, that a threshold temperature associated with the conductor has been exceeded; and based on determining that the threshold temperature has been exceeded, generate a control signal for a subsystem to perform a temperature management response.

In a further embodiment, the subsystem comprises a cooling component configured to cool the conductor using a mass flow, and wherein the temperature management response comprises increasing the mass flow using the cooling component.

In a further embodiment, the subsystem comprises a power supply configured to provide the electrical power to the conductor, and wherein the temperature management response comprises shutting off the electrical power to the conductor.

In a further embodiment, the one or more controllers are further configured to: determine, based on determining the threshold temperature has been exceeded, that a second threshold temperature associated with the conductor has been exceeded; and generate a second control signal for a second subsystem to perform a second temperature management response based on determining the second threshold temperature has been exceeded.

In a further embodiment, generating the control signal comprises generating a direct hardware signal and providing the direct hardware signal to the subsystem.

In a further embodiment, the conductor and the thermistor are arranged on a same substrate, wherein the conductor is a busbar, and wherein the thermistor is arranged adjacent to a connection point between the conductor and the same substrate.

In a further embodiment, the conductor, the thermistor, and a further conductor are arranged on a same substrate, wherein the thermistor is arranged adjacent to both the conductor and the further conductor on the same substrate, and wherein the threshold temperature is further associated with a region of the substrate comprising the conductor and the further conductor.

In a further embodiment, the one or more controllers comprise a first controller and a second controller, wherein the first controller comprises a baseboard management controller (BMC), wherein the second controller comprises a complex programmable logic device (CPLD), wherein the signal is a digital signal, and wherein obtaining the signal further comprises: obtaining, from an analog-to-digital convertor (ADC) that obtained an analog signal from the thermistor, the digital signal generated by the ADC based on the analog signal.

In a further embodiment, the one or more controllers are further configured to: obtain, by the BMC and from the ADC, the signal; and determine, by the BMC and based on the signal, that the threshold temperature has been exceeded, and wherein generating the control signal for the subsystem to perform the temperature management response further comprises: generating, by the BMC, a software-based signal for the CPLD to generate the control signal; and generating, by the CPLD and based on the software-based signal, a hardware-based control signal for the subsystem.

In a further embodiment, the BMC comprises the ADC, and wherein the first controller is separate from the second controller.

In a further embodiment, the one or more controllers are further configured to: determine, by the BMC and based on the signal, that the threshold temperature has been exceeded, and wherein generating the control signal for the subsystem to perform the temperature management response further comprises: generating, by the ADC, a hardware-based signal for the CPLD to generate the control signal; and generating, by the CPLD and based on the hardware-based signal, a further hardware-based control signal for the subsystem.

In a further embodiment, generating the control signal for the subsystem to perform the temperature management response further comprises: generating, by the ADC, a software-based signal for the BMC to log that the threshold temperature has been exceeded.

In an embodiment, a method, comprises: obtaining a signal based on a measurement of an electrical resistance of a thermistor, wherein the electrical resistance of the thermistor changes in response to a change in temperature of a conductor; determining, based on the signal, that a threshold temperature associated with the conductor has been exceeded; and generating a control signal for a subsystem to perform a temperature management response.

In a further embodiment, generating the control signal for the subsystem to perform the temperature management response further comprises generating the control signal for a cooling component to increase a mass flow to cool the conductor.

In a further embodiment, generating the control signal for the subsystem to perform the temperature management response further comprises generating the control signal for a power supply to shut off electrical power supplied by the power supply to the conductor.

In a further embodiment, the method further comprises: determining, based on determining the threshold temperature has been exceeded, that a second threshold temperature associated with the conductor has been exceeded; and generating a second control signal for a second subsystem to perform a second temperature management response based on determining the second threshold temperature has been exceeded.

In a further embodiment, generating the control signal for the subsystem to perform the temperature management response further comprises generating a direct hardware signal and providing the direct hardware signal to the subsystem.

In an embodiment, a non-transitory computer-readable medium has stored thereon a set of instructions, which if performed by one or more processors, cause the one or more processors to: obtain a signal based on a measurement of an electrical resistance of a thermistor, wherein the electrical resistance of the thermistor changes in response to a change in temperature of a conductor; determine, based on the signal, that a threshold temperature associated with the conductor has been exceeded; and generate a control signal for a subsystem to perform a temperature management response.

In a further embodiment, the instructions, which if performed by the one or more processors, further cause the one or more processors to: determine, based on determining the threshold temperature has been exceeded, that a second threshold temperature associated with the conductor has been exceeded; and generate a second control signal for a second subsystem to perform a second temperature management response based on determining the second threshold temperature has been exceeded.

In a further embodiment, generating the control signal for the subsystem to perform the temperature management response further comprises generating a direct hardware signal and providing the direct hardware signal to the subsystem.

It is noted that the techniques described herein may be embodied in executable instructions stored in a non-transitory computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic formats. A non-exhaustive list of exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached Figures are for illustrative purposes and that other arrangements are possible. For example, one or more of the elements described herein may be realized, in whole or in part, as an electronic hardware component. The elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

1. A circuit board, comprising:
a conductor;
a thermistor thermally coupled with the conductor and configured to change an electrical resistance of the thermistor in response to a change in temperature of the conductor; and
one or more controllers configured to:
obtain a signal based on a measurement of the electrical resistance of the thermistor;
determine, based on the signal, that a threshold temperature associated with the conductor has been exceeded; and
based on determining that the threshold temperature has been exceeded, generate a control signal for a subsystem to perform a temperature management response.

2. The circuit board of claim 1, wherein the subsystem comprises a cooling component configured to cool the conductor using a mass flow, and wherein the temperature management response comprises increasing the mass flow using the cooling component.

3. The circuit board of claim 1, wherein the subsystem comprises a power supply configured to provide electrical power to the conductor, and wherein the temperature management response comprises shutting off the electrical power to the conductor.

4. The circuit board of claim 1, wherein the one or more controllers are further configured to:
determine, based on determining the threshold temperature has been exceeded, that a second threshold temperature associated with the conductor has been exceeded; and
generate a second control signal for a second subsystem to perform a second temperature management response based on determining the second threshold temperature has been exceeded.

5. The circuit board of claim 1, wherein generating the control signal comprises generating a direct hardware signal and providing the direct hardware signal to the subsystem.

6. The circuit board of claim 1, wherein the conductor and the thermistor are arranged on a same substrate, wherein the conductor is a busbar, and wherein the thermistor is arranged adjacent to a connection point between the conductor and the same substrate.

7. The circuit board of claim 1, wherein the conductor, the thermistor, and a further conductor are arranged on a same substrate, wherein the thermistor is arranged adjacent to both the conductor and the further conductor on the same substrate, and wherein the threshold temperature is further associated with a region of the substrate comprising the conductor and the further conductor.

8. The circuit board of claim 1, wherein the one or more controllers comprise a first controller and a second controller, wherein the first controller comprises a baseboard management controller (BMC), wherein the second controller comprises a complex programmable logic device (CPLD), wherein the signal is a digital signal, and wherein obtaining the signal further comprises:
obtaining, from an analog-to-digital convertor (ADC) that obtained an analog signal from the thermistor, the digital signal generated by the ADC based on the analog signal.

9. The circuit board of claim 8, wherein the one or more controllers are further configured to:
obtain, by the BMC and from the ADC, the signal; and
determine, by the BMC and based on the signal, that the threshold temperature has been exceeded, and
wherein generating the control signal for the subsystem to perform the temperature management response further comprises:
generating, by the BMC, a software-based signal for the CPLD to generate the control signal; and
generating, by the CPLD and based on the software-based signal, a hardware-based control signal for the subsystem.

10. The circuit board of claim 8, wherein the BMC comprises the ADC, and wherein the first controller is separate from the second controller.

11. The circuit board of claim 8, wherein the one or more controllers are further configured to:
determine, by the BMC and based on the signal, that the threshold temperature has been exceeded, and
wherein generating the control signal for the subsystem to perform the temperature management response further comprises:
generating, by the ADC, a hardware-based signal for the CPLD to generate the control signal; and
generating, by the CPLD and based on the hardware-based signal, a further hardware-based control signal for the subsystem.

12. The circuit board of claim 11, wherein generating the control signal for the subsystem to perform the temperature management response further comprises:
generating, by the ADC, a software-based signal for the BMC to log that the threshold temperature has been exceeded.

13. A method, comprising:
obtaining a signal based on a measurement of an electrical resistance of a thermistor, wherein the electrical resistance of the thermistor changes in response to a change in temperature of a conductor;
determining, based on the signal, that a threshold temperature associated with the conductor has been exceeded; and
generating a control signal for a subsystem to perform a temperature management response.

14. The method of claim 13, wherein generating the control signal for the subsystem to perform the temperature management response further comprises generating the control signal for a cooling component to increase a mass flow to cool the conductor.

15. The method of claim 13, wherein generating the control signal for the subsystem to perform the temperature management response further comprises generating the control signal for a power supply to shut off electrical power supplied by the power supply to the conductor.

16. The method of claim 13, further comprising:
determining, based on determining the threshold temperature has been exceeded, that a second threshold temperature associated with the conductor has been exceeded; and
generating a second control signal for a second subsystem to perform a second temperature management response based on determining the second threshold temperature has been exceeded.

17. The method of claim 13, wherein generating the control signal for the subsystem to perform the temperature management response further comprises generating a direct hardware signal and providing the direct hardware signal to the subsystem.

18. A non-transitory computer-readable medium having stored thereon a set of instructions, which if performed by one or more processors, cause the one or more processors to:
obtain a signal based on a measurement of an electrical resistance of a thermistor, wherein the electrical resistance of the thermistor changes in response to a change in temperature of a conductor;
determine, based on the signal, that a threshold temperature associated with the conductor has been exceeded; and
generate a control signal for a subsystem to perform a temperature management response.

19. The non-transitory computer-readable medium of claim 18, wherein the instructions, which if performed by the one or more processors, further cause the one or more processors to:
determine, based on determining the threshold temperature has been exceeded, that a second threshold temperature associated with the conductor has been exceeded; and
generate a second control signal for a second subsystem to perform a second temperature management response based on determining the second threshold temperature has been exceeded.

20. The non-transitory computer-readable medium of claim 18, wherein generating the control signal for the subsystem to perform the temperature management response further comprises generating a direct hardware signal and providing the direct hardware signal to the subsystem.
